(19) United States
(12) Patent Application Publication
(10) Pub. No.: US 2025/0054912 A1
(43) Pub. Date: Feb. 13, 2025

(54) INTEGRATED CIRCUIT DEVICE INCLUDING DIES ARRANGED FACE-TO-FACE

(71) Applicant: Microchip Technology Incorporated, Chandler, AZ (US)

(72) Inventor: Julius Kovats, Manitou Springs, CO (US)

(73) Assignee: Microchip Technology Incorporated, Chandler, AZ (US)

(21) Appl. No.: 18/540,971

(22) Filed: Dec. 15, 2023

Related U.S. Application Data
(60) Provisional application No. 63/531,385, filed on Aug. 8, 2023.

(51) Int. Cl. H01L 25/065; H01L 23/00; H01L 23/498

(52) U.S. Cl. CPC H01L 25/0657; H01L 23/49816; H01L 24/05; H01L 24/13; H01L 2224/05009; H01L 2224/05025; H01L 2224/13025; H01L 2224/13026; H01L 2225/0651; H01L 2225/06513; H01L 2924/01029; H01L 2924/141; H01L 2924/15311

(57) ABSTRACT

A method of forming an integrated circuit (IC) device includes forming a first die block including a first die block substrate, a first die at least partially embedded in the first die block substrate, first die contacts located in a first die footprint, and first die block contacts laterally outside the first die footprint. A second die having a larger footprint than the first die footprint, and including second die inner contacts and second die outer contacts, is arranged face-to-face and spatially aligned relative to the first die. The second die is bonded to the first die block by a bonding process including (a) bonding respective second die inner contacts to respective first die contacts to define inner electrical connections between the first and second dies and (b) bonding respective second die outer contacts to respective first die block contacts to define outer electrical connections outside the first die footprint.

### RELATED APPLICATION

This application claims priority to commonly owned U.S. Provisional Patent Application No. 63/531,385 filed Aug. 8, 2023, the entire contents of which are hereby incorporated by reference for all purposes.

### TECHNICAL FIELD

The present disclosure relates to integrated circuit (IC) devices including dies arranged face-to-face, and methods of forming such IC devices.

### BACKGROUND

Semiconductor wafer fabrication technology has become increasingly complex, costly and time consuming to develop. Many IC devices, for example many IC packages, include multiple different types of IC dies (also referred to herein as chips or chiplets) that perform different functions of the respective device. Such devices may be referred to as multi-die IC devices. The different dies in a respective multi-die IC device (e.g., an analog chiplet and a digital chiplet) are commonly formed together (concurrently), for example by forming the dies side-by-side on a common wafer or panel. However, for some multi-die IC devices, for example certain microcontrollers, it may be advantageous or preferred to manufacture the different dies (e.g., analog chiplets and digital chiplets) separately (in some cases using different manufacturing technologies) and subsequently assemble the various dies together.

There is a need for improved multi-die IC devices and methods of forming multi-die IC devices.

### SUMMARY

The present disclosure provides multi-die IC devices including multiple dies (e.g., chips or “chiplets”) mounted face-to-face, and methods of forming such IC devices. Some examples provide die-level integration between two or more dies, e.g., an analog die and a digital die, for example using panel level assembly technology. Some examples provide an assembly combining two or more dies mounted in a face-to-face configuration using RDL (redistribution layer) routing, conductive contacts between the multiple dies (e.g., copper pillar bumps or posts), and solder wettable pads or bumps. Pick and place equipment may be utilized to position and align respective dies.

In some examples, different dies included in the multi-die IC device may be formed separately (e.g., on separate panels) and then combined, thereby allowing different fabrication technologies to be used for the different dies. For example, for a multi-die IC device including an analog die and a digital die produced separately and then mounted together in the multi-die IC device, a more advanced (and/or expensive) fabrication technology may be used for producing the digital die than the analog dies, which may thereby save cost and/or time as compared with conventional processes in which both the digital and analog dies are produced together.

In some examples, multiple instances of the multi-die IC device may be produced on a common panel or other substrate, for example using panel-level packaging (PLP) technology. For example, to produce a group of multi-die IC devices each including a digital die combined with an analog die, an array of digital dies may be formed on a first wafer or first panel (e.g., using PLP technology), an array of analog dies may be formed on a second wafer or second panel (e.g., using PLP technology), the analog dies may be singulated (diced) and respectively positioned, aligned, and mounted to respective instances of the digital dies on the first wafer/panel, and the first wafer/panel may then be singulated (diced) to produce a group of discrete multi-die IC devices including a respective analog die mounted to a respective digital die.

In some examples, a multi-die IC device may include a first die block including the first die (e.g., a digital die), first inner contacts extending from the first die, and first die block contacts formed in or on the first die block at locations outside a lateral footprint of the first die (i.e., laterally spaced apart from the first die). In some examples, the first die block contacts may be formed relative to the first die using adaptive patterning, and may be formed in or connected to RDL (redistribution layer) routing, for example.

The multi-die IC device may also include a second die (e.g., an analog die) mounted to the first die block. The second die may include second die inner contacts corresponding with respective first die contacts, and second die outer contacts corresponding with respective first die block contacts. The second die is mounted to the first die block, wherein (a) respective second die inner contacts are bonded (e.g., solder bonded) to respective first die contacts to define a plurality of inner electrical connections between the second die and the first die and (b) respective second die outer contacts are bonded (e.g., solder bonded) to respective first die block contacts to define a plurality of outer electrical connections outside the lateral footprint of the first die.

In some examples, the first die block may include first alignment contacts and the second die may include second alignment contacts. The first alignment contacts and second alignment contacts may be used for aligning (e.g., translationally and/or rotationally) the second die relative to the first die block. The first alignment contacts and second alignment contacts may be located radially outwardly relative to other contacts between the second die and first die block, and may have a larger diameter or width relative to other contacts between the second die and first die block.

One aspect provides a method including forming an integrated circuit (IC) device. The method includes forming a first die block including a first die block substrate comprising a mold compound, a first die at least partially embedded in the first die block substrate, a plurality of first die contacts located in a lateral footprint of the first die, and a plurality of first die block contacts located laterally outside the lateral footprint of the first die. The method includes arranging a second die in a face-to-face orientation relative to the first die, wherein a lateral footprint of the second die is larger than a lateral footprint of the first die, and wherein the second die includes (a) a plurality of second die inner contacts and (b) a plurality of second die outer contacts. The method includes spatially aligning the second die relative to the first die block, and performing a bonding process to bond the second die to the first die block, wherein the bonding process includes (a) bonding respective second die inner contacts to respective first die contacts to define a plurality of inner electrical connections between the second die and the first die and (b) bonding respective second die outer contacts to respective first die block contacts to define a plurality of outer electrical connections outside the lateral footprint of the first die.

In some examples, the first die block includes a laterally extending conductor formed over the first die block substrate, the laterally extending conductor connected to a respective one of the plurality of first die block contacts and extending laterally outside the lateral footprint of the second die, wherein the laterally extending conductor comprises a bond pad for bonding the IC device to another IC device.

In some examples, the respective first die block contact is bonded to a respective one the second die outer contacts to define an electrical connection between the laterally extending conductor and the second die.

In some examples, the first die block includes a plurality of laterally extending conductors, wherein respective laterally extending conductors define electrical connections between the first die and respective ones of the plurality of first die block contacts located laterally outside the lateral footprint of the first die.

In some examples, the plurality of first die contacts comprise a first plurality of pillars extending upwardly from a first side of the first die, and the plurality of first die block contacts comprise a second plurality of pillars extending upwardly from the first die block substrate.

In some examples, after spatially aligning the second die relative to the first die block, the plurality of first die contacts and the plurality of first die block contacts are located in the lateral footprint of the second die.

In some examples, one or more first die block contacts of the plurality of first die block contacts define one or more first alignment contacts, one or more second die outer contacts of the plurality of second die outer contacts define one or more second alignment contacts, and spatially aligning the second die relative to the first die block comprises aligning the one or more second alignment contacts with the one or more first alignment contacts. The method may include bonding respective second alignment contacts to respective first alignment contacts.

In some examples, a respective diameter of a respective first alignment contact of the one or more first alignment contacts is larger than a respective diameter of a respective first die contact of the plurality of first die contacts.

In some examples, a respective diameter of a respective second alignment contact of the one or more second alignment contacts is larger than a respective diameter of a respective second die outer contact of the plurality of second die outer contacts.

In some examples, the first die comprises a digital die, and the second die comprises an analog die.

In some examples, the method includes providing a flux between the first die and the second die prior to performing the bonding process, and wherein the bonding process comprises a mass reflow process.

In some examples, the method includes forming the plurality of first die contacts and the plurality of first die block contacts concurrently.

In some examples, forming the first die block includes forming at least one vertically-extending alignment guide, and spatially aligning the second die relative to the first die block comprises using the at least one vertically-extending alignment guide to physically constrain a spatial alignment of the second die relative to the first die block.

In some examples, the method includes forming a panel-level structure, including arranging a plurality of first dies, including the first die, on a panel-level carrier, and overmolding the plurality of first dies to form a panel-level substrate with the plurality of first dies embedded in the panel-level substrate, wherein a respective portion of the panel-level substrate defines the first die block substrate, and wherein the first die block includes the first die block substrate having the first die embedded therein. After aligning and bonding the second die to the first die block, a singulation process may be performed to singulate the first die block having the first die embedded therein and the second die mounted thereto.

In some examples, the method includes mounting the IC device in a quad flat no-leads (QFN) package.

One aspect provides an integrated circuit (IC) device including a first die block including a first die block substrate comprising a mold compound, a first die at least partially embedded in the first die block substrate, a plurality of first die contacts located in a lateral footprint of the first die, and a plurality of first die block contacts located laterally outside the lateral footprint of the first die. The IC devices includes a second die mounted to the first die in a face-to-face orientation.

A lateral footprint of the second die is larger than a lateral footprint of the first die. The second die includes a plurality of second die inner contacts bonded to respective ones of the plurality of first die contacts to define a plurality of inner electrical connections between the second die and the first die, and a plurality of second die outer contacts bonded to respective ones of the plurality of first die block contacts to define plurality of outer electrical connections outside the lateral footprint of the first die.

In some examples, the IC device includes a laterally extending conductor formed over the first die block substrate, wherein the laterally extending conductor is electrically connected to the second die through a respective one of the plurality of first die block contacts and a respective one of the plurality of second die outer contacts.

In some examples, the first die comprises a digital die, and the second die comprises an analog die.

In some examples, the IC device comprises a quad flat no-leads (QFN) package.

One aspect provides an IC device including a first die block and a second die mounted to the first die in a face-to-face orientation. The first die block includes a first die block substrate comprising a mold compound, a first die at least partially embedded in the first die block substrate, the first die having a first die lateral footprint, and a plurality of first die contacts located within the first die lateral footprint. The second die has a second die lateral footprint and includes a plurality of second die contacts located within the second die lateral footprint, wherein respective second die contacts are bonded to respective first die contacts to define a plurality of electrical connections between the second die and the first die. The IC device includes a laterally extending conductor formed on or in the first die block, wherein the laterally extending conductor (a) is connected to at least one of a respective first die contact or a respective second die contact at a respective location within the first die lateral footprint and the second die lateral footprint, (b) extends laterally outside the first die lateral footprint and the second die lateral footprint, and (c) is connected to or defines an external contact.

In some examples, an area of the second die lateral footprint differs from an area of the first die lateral footprint by less than 25%.

One aspect provides a method, including arranging a plurality of first dies spaced apart from each other on a carrier, wherein a respective first die includes a respective plurality of first die contacts, and overmolding the plurality of first dies to form a substrate with the plurality of first dies embedded in the substrate, wherein the substrate with the plurality of first dies embedded in the substrate defines an array of first die blocks, wherein a respective die block of the array of first die blocks includes the respective first die embedded in a respective portion of the substrate. The method includes forming a plurality of respective first die block contacts on the respective first die block, wherein the respective first die block contacts are located laterally outside a lateral footprint of the respective first die, and mounting and bonding a plurality of second dies to the plurality of first die blocks. Mounting and bonding a respective second die to a respective first die block includes arranging the respective second die in a face-to-face orientation relative to the respective first die block, wherein a lateral footprint of the respective second die is larger than the lateral footprint of the respective first die, and wherein the respective second die includes (a) a plurality of respective second die inner contacts and (b) a plurality of respective second die outer contacts; spatially aligning the respective second die relative to the respective first die block; and performing a bonding process to bond the respective second die to the respective first die block, wherein the bonding process includes (a) bonding the plurality of respective second die inner contacts to the plurality of respective first die contacts to define a plurality of inner electrical connections between the respective second die and the respective first die and (b) bonding the plurality of respective second die outer contacts to the plurality of respective first die block contacts to define a plurality of outer electrical connections. The array of first die blocks may be singulated.

In some examples, the respective first die comprises a digital die, and the respective second die comprises an analog die.

### BRIEF DESCRIPTION OF THE DRAWINGS

Example aspects of the present disclosure are described below in conjunction with the figures, in which:

FIGS. 1A and 1B show a top view and cross-sectional side view, respectively, of an example multi-die IC device including a second die mounted on a first die block including a first die, according to one example;

FIGS. 2-8 show an example process for forming the example multi-die IC device shown in FIGS. 1A-1B, e.g., using panel level processing (PLP), according to one example;

FIG. 9A is a side cross-sectional view of an example flat no-leads IC package including an example multi-die IC device mounted on a leadframe, according to one example;

FIG. 9B is a side cross-sectional view of an example flat no-leads IC package including an example multi-die IC device including leads extending from or otherwise connected to lateral conductors formed integral with a first die block of the multi-die IC device, according to one example;

FIG. 9C is a side cross-sectional view of an example IC package including an example multi-die IC device wire bonded to an electronic device, according to one example;

FIGS. 10A and 10B show respective top views of the example multi-die IC device shown in FIGS. 1A-1B, illustrating an example alignment of the second die relative to the underlying first die block, according to one example; and

FIGS. 11A and 11B show a top view and cross-sectional side view, respectively, of another example multi-die IC device including a second die mounted on a first die, wherein the second die has a similar lateral footprint as the first die, according to one example.

It should be understood that the reference number for any illustrated element that appears in multiple different figures has the same meaning across the multiple figures, and the mention or discussion herein of any illustrated element in the context of any particular figure also applies to each other figure, if any, in which that same illustrated element is shown.

### DETAILED DESCRIPTION

The present disclosure provides multi-die IC devices including multiple dies mounted face-to-face, and methods of forming such IC devices. Some examples provide die-level integration between two or more dies, e.g., an analog die and a digital die, for example using panel level assembly technology. Some examples provide an assembly combining multiple dies mounted in a face-to-face configuration using RDL (redistribution layer) routing, conductive contacts between the multiple dies (e.g., copper pillar bumps or posts), and solder wettable pads or bumps. Pick and place equipment may utilize respective alignment features to position and align respective dies.

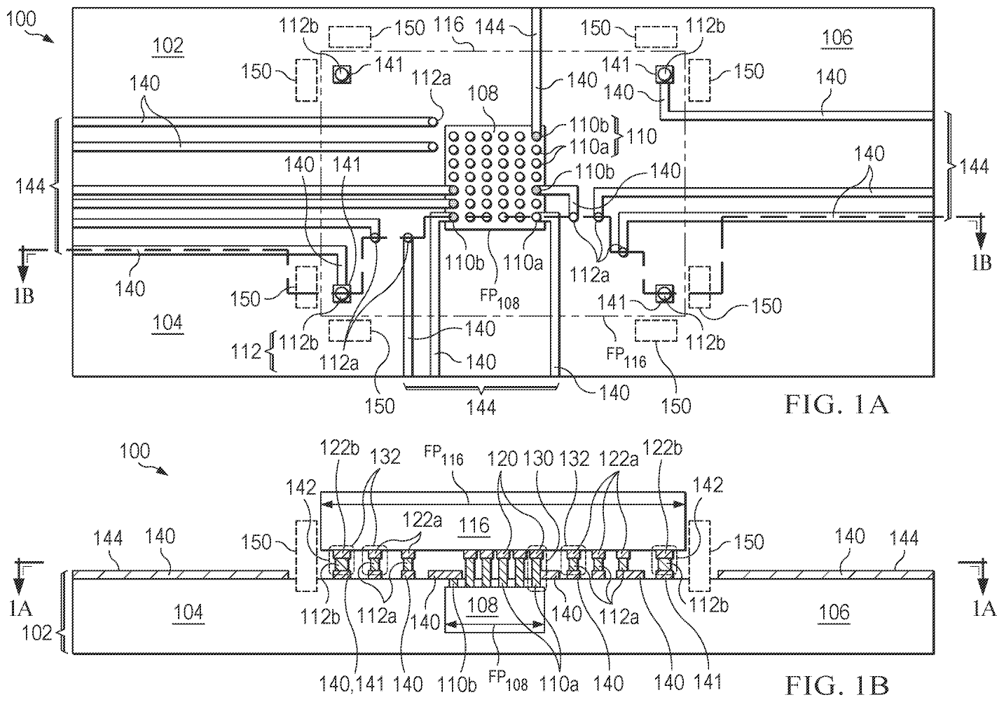

FIGS. 1A and 1B show an example multi-die IC device 100 (also referred to herein as “device 100” for convenience) according to one example. FIG. 1A shows a top view indicated at line 1A-1A shown in FIG. 1B, and FIG. 1B shows a cross-sectional view through segmented cut line 1B-1B shown in FIG. 1A. As shown in FIGS. 1A-1B, device 100 includes a first die block 102 and a second die 116 mounted to the first die block 102. The first die block 102 may include a first die block substrate 104 comprising a mold compound 106, a first die 108 at least partially embedded in the first die block substrate 104, a plurality of first die contacts 110 (e.g., including first die contacts 110a and/or 110b, as discussed below) located in a lateral footprint FP₁₀₈ of the first die 108, and a plurality of first die block contacts 112 (e.g., including first die block contacts 112a and/or 112b, as discussed below) located laterally outside the lateral footprint FP₁₀₈ of the first die 108. The mold compound 106 may comprise an epoxy mold compound (EMC) or other suitable dielectric compound.

In some examples, the first die 108 comprises a digital die, and the second die 116 comprises an analog die. For example, the device 100 may comprise a heterogenous microcontroller, wherein the first die 108 includes digital component(s) and the second die 116 includes analog component(s) of the heterogenous microcontroller.

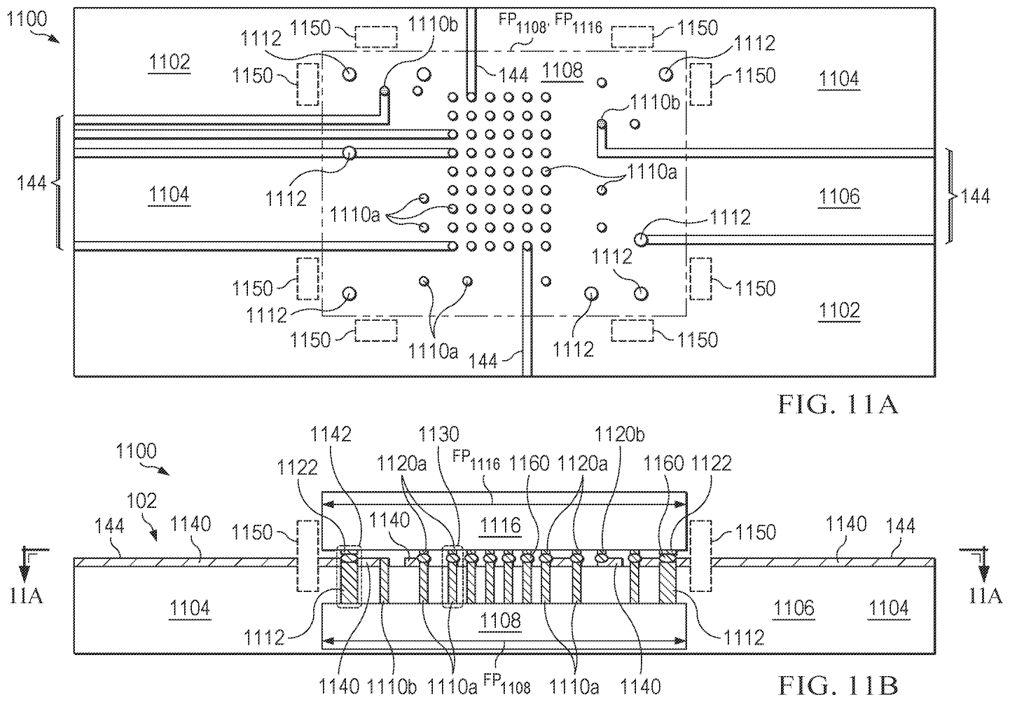

The second die 116 may be mounted to the first die block 102 in a face-to-face orientation, i.e., wherein the second die 116 and first die 108 are arranged in a face-to-face orientation. In this example, a lateral footprint FP₁₁₆ of the second die 116 is larger than the lateral footprint FP₁₀₈ of the first die 108. In other examples, e.g., as shown in FIGS. 11A-11B discussed below, the second die 116 may have a similar (or smaller) lateral footprint than the first die 108.

The second die 116 includes (a) a plurality of second die inner contacts 120 bonded to respective first die contacts 110 to define a plurality of inner electrical connections 130 between the second die 116 and the first die 108, and (b) a plurality of second die outer contacts 122 (e.g., including second die outer contacts 122a and/or 122b, as discussed below) bonded to respective first die block contacts 112 to define a plurality of outer electrical connections 132 outside the lateral footprint FP₁₀₈ of the first die 108.

Respective ones of the first die contacts 110, first die block contacts 112, second die inner contacts 120, and second die outer contacts 122 may comprise any suitable type or types of conductive contacts, including for example (a) conductive pillars (e.g., copper pillars suitable for copper pillar bumping), (b) contact pads, e.g., solder wettable pads or solder plated pads (e.g., SnAgCu plated pads), or other type(s) of conduct contact structures. Conductive pillars may extend (in the z-direction) from an outer surface of the respective first die 108 or second die 116. Contact pads may be flush with, or may extend (in the z-direction) from, an outer surface of the respective first die 108 or second die 116 in the z-direction.

Respective first die contacts 110 may be bonded to respective second die inner contacts 120 (to form respective inner electrical connections 130), and respective first die block contacts 112 may be bonded to respective second die outer contacts 122 (to form respective outer electrical connections 132) using any suitable bonding process and/or materials. For example, respective contacts may be bonded together by soldering, by thermocompression bonding, or using an adhesive.

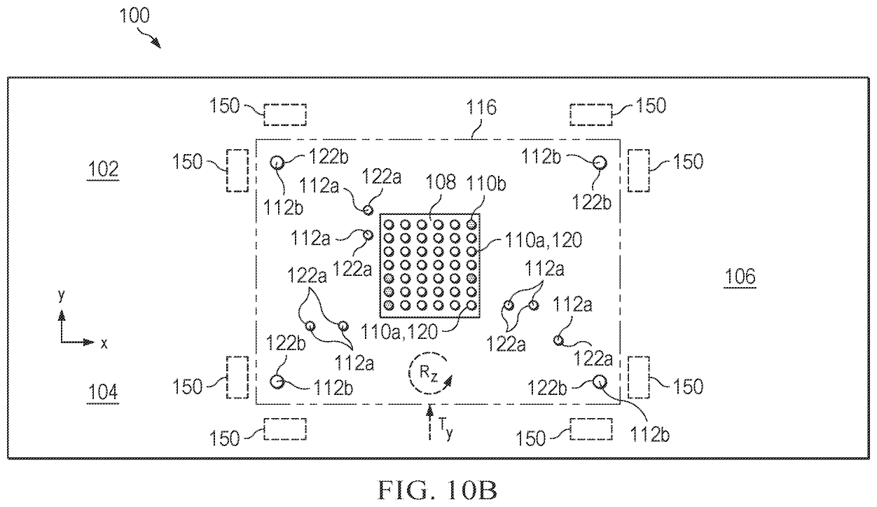

In some examples, some or all of the first die contacts 110 may be bonded to respective second die inner contacts 120 (to form respective inner electrical connections 130), and/or some or all of the first die block contacts 112 may be bonded to respective second die outer contacts 122 (to form respective outer electrical connections 132) using a solder reflow process. In solder reflow, e.g., a mass reflow, solder material may be applied to the second die 116 and/or the first die block 102 (before mounting the second die 116 to the first die block 102), the second die 116 may be mounted on the first die block 102, and assembled device 100 may be passed through a heated furnace environment at a temperature exceeding the melting point of the solder joints, thereby forming solid mechanical and electrical connections between respective first die contacts 110, 112 and respective second die contacts 120, 122. In some examples, e.g., as discussed below with reference to FIGS. 10A-10B, the solder reflow process may improve an alignment (translational and/or rotational alignment) of the second die 116 relative to the first die 108. In another example, a Laser Assisted Bonding (LAB) process may be used, wherein laser radiation is directed through the device 100 to create localized heat near the solder joints, which may reduce potential warpage effects associated with other bonding techniques.

The first die block 102 may include laterally extending conductors 140 (also referred to as lateral conductors, for convenience) extending laterally (e.g., in the x-direction and/or y-direction shown in FIGS. 1A-1B) on a top surface of the first die block substrate 104 and/or embedded within the first die block substrate 104. Respective lateral conductors 140 may be electrically connected to respective first die contacts 110, respective second die inner contacts 120, respective first die block contacts 112, respective second die outer contacts 122, respective inner electrical connections 130, and/or respective outer electrical connections 132, for example to allow electrical connection between the first die 108 and/or the second die 116 and external electronics (i.e., external to device 100). Lateral conductors 140 may comprise conductive traces, wires, metal lines, or other conductive elements. The example shown in FIGS. 1A-1B includes lateral conductors 140 (e.g., copper traces or wires) formed on a top side of the first die block 104.

The first die contacts 110, the first die block contacts 112, second die inner contacts 120, second die outer contacts 122, and lateral conductors 140 may be selectively connected to each other to define various electrical connections between the first die 108 and second die 116, between the first die 108 and respective external electronics (i.e., distinct from device 100), and/or between the second die 116 and respective external electronics (i.e., distinct from device 100).

As shown in FIGS. 1A-1B, the first die contacts 110 may include (a) one or more first die contacts 110a bonded to respective second die inner contacts 120 to form respective inner electrical connections 130, and optionally (b) one or more first die contacts 110b connected to respective lateral conductors 140 (e.g., copper traces) formed on, or in, the first die block substrate 104. The first die block contacts 112 may include one or more first die block contacts 112a connected to respective second die outer contacts 122a to define respective outer electrical connections 132. In addition, in some examples the first die block contacts 112 may optionally include one or more first die block contacts 112b to bond with respective second die outer contacts 122b to facilitate spatial alignment (e.g., translational and/or rotational alignment) of the second die 116 relative to the first die 108, e.g., as discussed below with reference to FIGS. 10A-10B. The first die block contacts 112b may thus be referred to as first alignment contacts 112b.

As shown in FIGS. 1A-1B, the second die outer contacts 122 may include one or more second die outer contacts 122a bonded to respective first die block contacts 112a to form respective outer electrical connections 132 (as discussed above). In addition, in some examples the second die outer contacts 122 may optionally include one or more second die outer contacts 122b to bond with respective first alignment contacts 112b to facilitate spatial alignment (e.g., translational and/or rotational alignment) of the second die 116 relative to the first die 108. The second die outer contacts 122b may thus be referred to as second alignment contacts 122b. For example, as shown in FIG. 1B, a plurality of second die outer contacts 122b (in this example, four second die outer contacts 122b) may be aligned with and bonded to respective first alignment contacts 112b (in this example, four first alignment contacts 112b, as shown in FIG. 1A) to facilitate spatial alignment of the second die 116 relative to the first die 108. Respective second die outer contacts 122b bonded to respective first alignment contacts 112b define respective alignment connections 142.

Respective first alignment contacts 112b may be formed on respective alignment contact bases 141, which may or may not be connected to respective lateral conductors 140, e.g., formed in a common metal layer as the lateral conductors 140.

As shown in FIGS. 1A-1B, a respective alignment connection 142 may also define an outer electrical connection 132, e.g., to connect the second die 116 to external electronics via (a) the respective alignment connection 142, (b) a respective alignment contact base 141 on which the respective first alignment contact 112b (of the respective alignment connection 142) is formed, and (c) a respective lateral conductor 140 connected to the respective alignment contact base 141. Alternatively, a respective alignment connection 142 may not form an outer electrical connection 132; for such alignment connection 142 the respective first alignment contact 112b may be formed on a respective alignment contact base 141 physically separated from lateral conductors 140.

In some examples, the second die outer contacts 122b may be located radially outwardly from second die outer contacts 122a, with respect to a centroid of the lateral footprint of the second die 116. In addition, in some examples, respective first die block contacts 112b (i.e., first alignment contacts 112b) may have a larger diameter (e.g., in the x-y plane) than respective first die block contacts 112a, and respective second die outer contacts (i.e., second alignment contacts) 122b may have a larger diameter (e.g., in the x-y plane) than respective second die outer contacts 122a. The larger diameters of the first alignment contacts 112b and second alignment contacts 122b may help with the spatial alignment of the of the second die 116 relative to the first die 108, e.g., as discussed below with reference to FIGS. 10A-10B.

Respective lateral conductors 140 may be selectively connected to the first die 108, the second die 116, or both the first die 108 and second die 116. For examples, as shown in FIG. 1, selected lateral conductors 140 may be (a) connected to the second die 116 via a respective outer electrical connections 132, or (b) connected to first die 108 via a respective first die contact 110b, or (c) connected to both first die 108 and second die 116 via a respective inner electrical connections 130, or (d) connected between a respective first die contact 110b and a respective outer electrical connections 132, e.g., to connect the first die 108 to the second die 116 via a second die outer contact 122a (e.g., at a location outside the lateral footprint of the first die 108). The term “or”, as used throughout, is meant to be inclusive, i.e. any combination of one or more of the alternates, without limitation.

Some lateral conductors 140, e.g., as indicated at 144 in FIGS. 1A-1B, may define a bond pad for bonding the device to one or more external electronics, e.g., by solder ball and/or wire bond connections. In some examples, the device 100 comprises a quad flat no-leads (QFN) package, or a component of a QFN package, wherein lateral conductors 144 define solder lands or pads.

The first die block 102 may optionally include at least one vertically-extending alignment guide 150 projecting upwardly from the first die block substrate 104. The example shown in FIGS. 1A-1B includes a plurality of vertically-extending alignment guides 150 that define an internal area into which the second die 116 may be received during mounting of the second die 116 to the first die block 102. The vertically-extending alignment guides 150 may physically constrain a spatial alignment of the second die 116 relative to the first die block 102, to thereby help spatially align the second die 116 relative to the first die block 102. In the illustrated example, the vertically-extending alignment guides 150 may physically constrain the respective corners of the second die 116. The vertically-extending alignment guides 150 may be formed from metal (e.g., copper), a polymer, or other material.

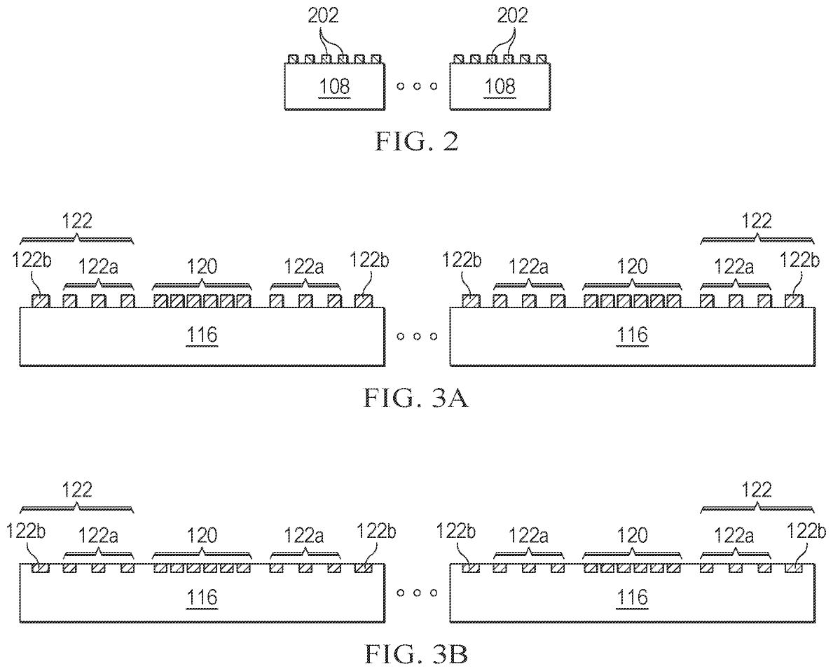

FIGS. 2-8 show an example process for forming the example multi-die IC device 100 using panel level processing (PLP). The multi-die IC device 100 may be formed using panel level processing (PLP), wherein an array of multi-die IC devices (including the multi-die IC device 100) may be formed concurrently on a common panel. The array of multi-die IC devices formed on the common panel may include multiple instances of the example multi-die IC device 100 (e.g., as shown in the example process of FIGS. 2-8), or may include different types of IC devices (e.g., one or more instances of the example multi-die IC device 100 and one or more other multi-die IC devices.

As shown in FIG. 2, a plurality of first dies 108 are formed or otherwise provided, and a respective array of first die contact elements 202 is formed on respective first dies 108. In one example, first die contact elements 202 may comprise copper pillars or posts (e.g., copper pillars or posts formed by a copper plating process) extending from a front side of respective first dies 108. In other examples, first die contact elements 202 may comprise contact pads formed during the manufacturing of first dies 108; such contact pads may be flush with, or may extend (in the z-direction) from, an outer surface of the respective first die 108.

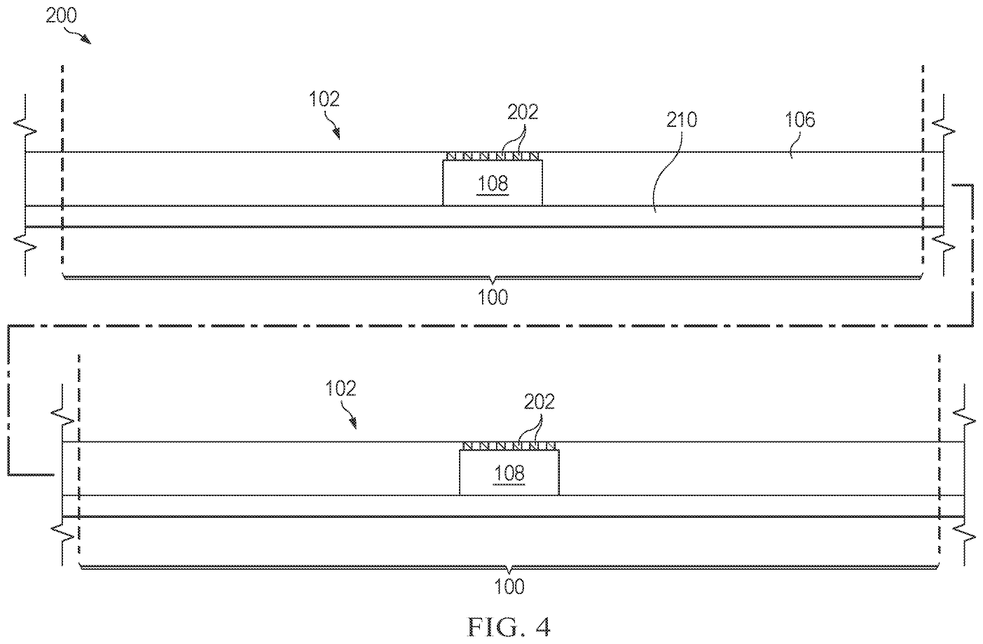

As shown in FIGS. 3A and 3B (showing two alternative examples), a plurality of second dies 116 are formed or otherwise provided, and respective second die inner contacts 120 and second die outer contacts 122 (including second die outer contacts 122a or second die outer contacts 122b) are formed on an outer surface of respective second dies 116. In the example shown in FIG. 3A, second die outer contacts 120 and second die outer contacts 122 may comprise pillars or posts (e.g., copper pillars or posts formed by a copper plating process) extending from a front side of respective second dies 116. In the example shown in FIG. 3B, second die outer contacts 120 and second die outer contacts 122 may comprise contact pads (e.g., solder wettable pads) or solder plated pads (e.g., SnAgCu plated pads), or other type(s) of conduct contact structures.

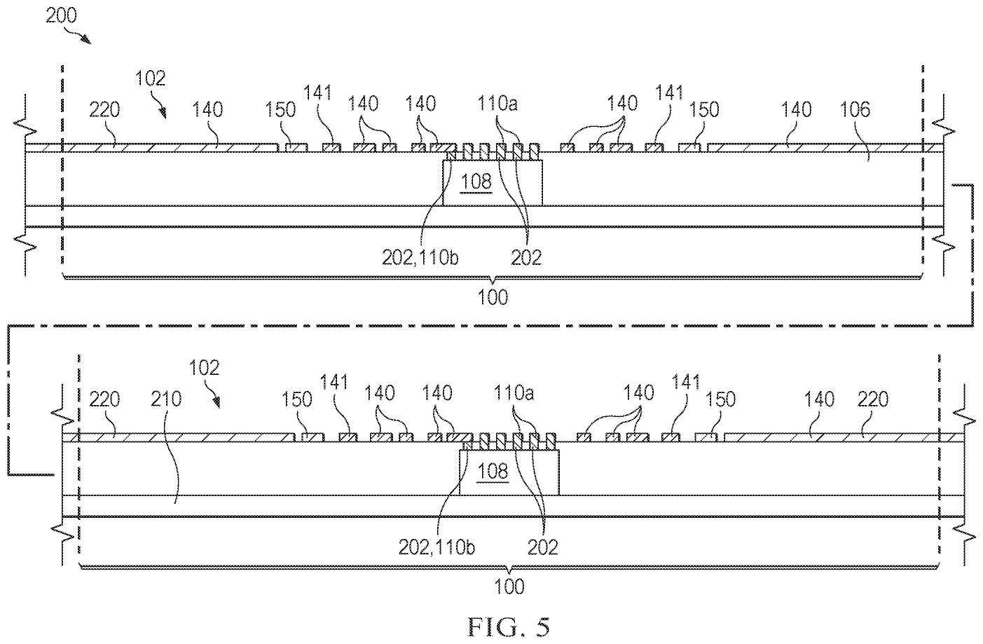

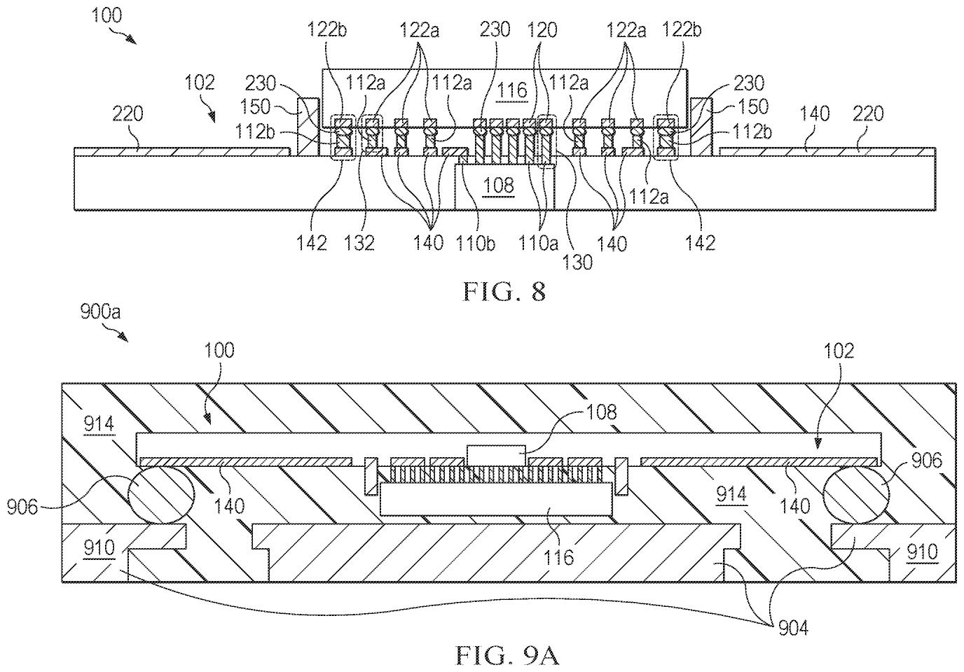

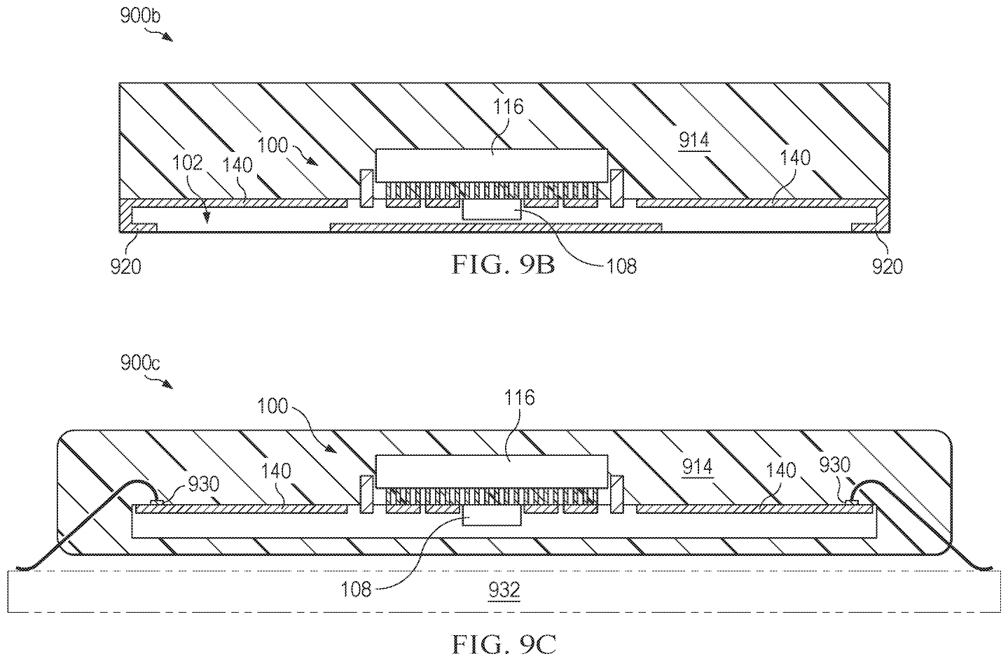

As shown in FIG. 4, a portion of a panel-level substrate 200 may be formed by mounting a plurality of first dies 108 (e.g., including first die contact elements 202) face-up and spaced apart from each other on panel-level carrier 210, and overmolded with the mold compound 106 (e.g., EMC). The portion of the panel-level substrate 220 shown in FIG. 4 includes two instances of the multi-die IC device 100 under construction, with respective instances of the multi-die IC device 100 including a respective first die block 102, the respective first die block 102 including a respective first die 108 mounted on the panel-level carrier 210 at least partially covered or encapsulated by the mold compound 106. The instances of the multi-die IC device 100 may be constructed on the panel-level carrier 210 as described below, and singulated into discrete multi-die IC devices 100 as shown in FIGS. 7 and 8 discussed below.

A grinding or other planarization process may be performed on a top side of the panel-level substrate 200 to planarize the mold compound 212 and expose the first die contact elements 202 projecting upwardly from the respective first dies 108.

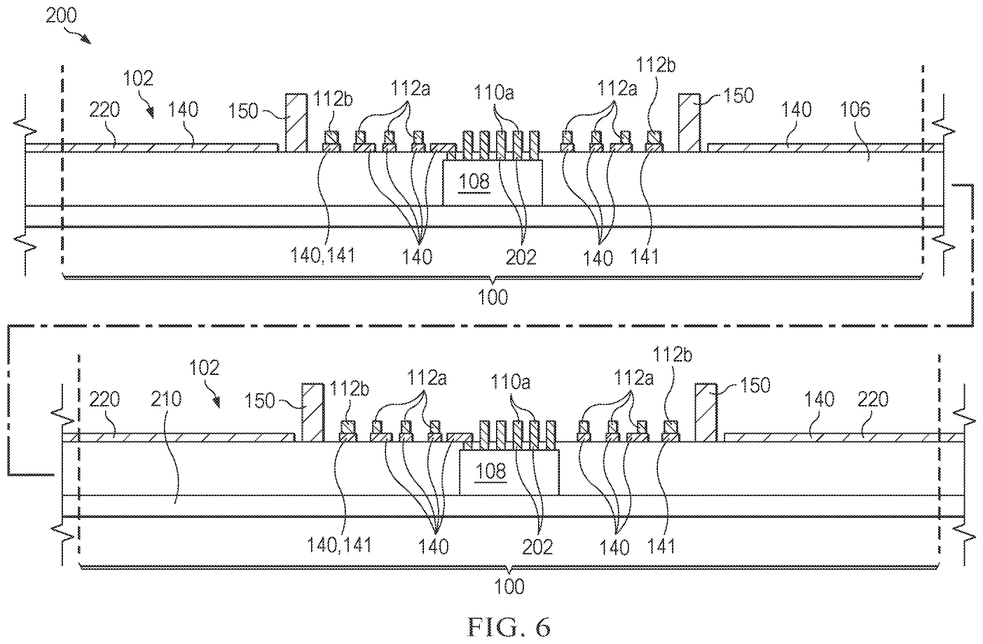

As shown in FIG. 5, a conductive layer 220 may be formed on the panel-level substrate 210. The conductive layer 220 may include various elements, e.g., including (a) lateral conductors 140, (b) lower base portions of respective first die contacts 110a, formed on respective first die contact elements 202 (wherein respective first die contact elements 202 define a portion of respective first die contacts 110a being formed), (c) alignment contact bases 141 of respective first alignment contacts 112b, and/or a lower base portion of respective vertically-extending alignment guides 150. As shown, a respective lateral conductor 140 formed in contact with a respective first die contact element 202 may define a respective first die contact 110b.

The conductive layer 220 may comprise copper, aluminum, or other conductive material. In some examples, the conductive layer 220 may comprise RDL (e.g., copper RDL) formed using an adaptive patterning process. Respective lateral conductors 140 may be patterned to match the locations of respective second die outer contacts 122a of respective second dies 116 (not shown) to be subsequently mounted to respective first dies 108.

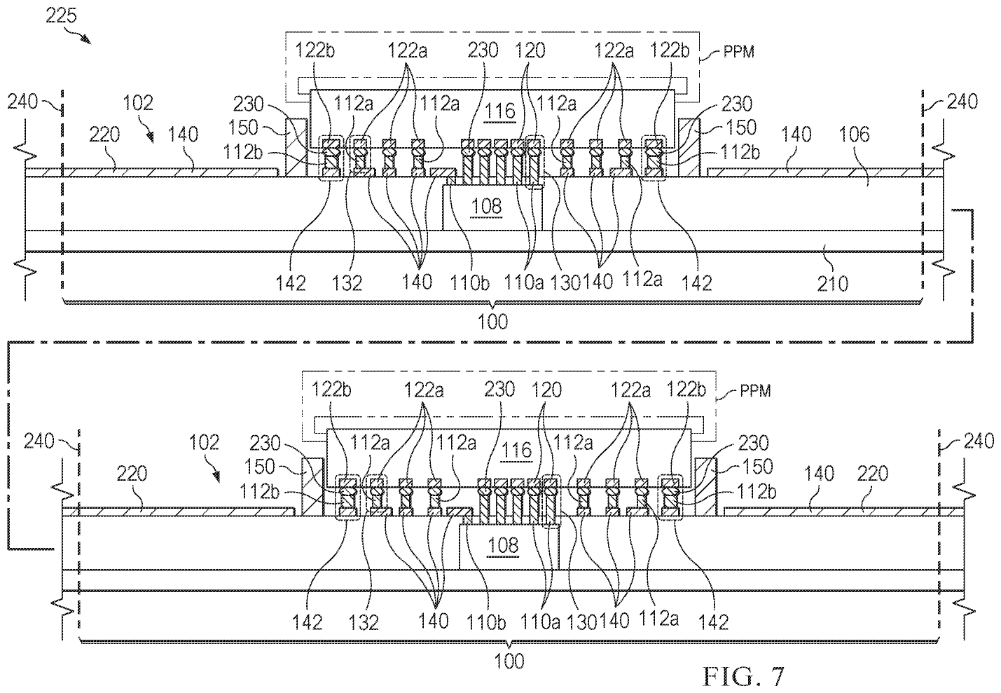

As shown in FIG. 6, one or more plating processes may be performed to extend selected structures vertically, i.e., to increase the vertical (z-direction) height of selected structures. For example, one or more plating processes may be performed to (a) extend the height of respective first die contacts 110a projecting above the first die 108, (b) form first die block contacts 112a on respective lateral conductors 140, (c) form first die block contacts 112b (first alignment contacts 112b) on respective alignment contact bases 141, and (d) extend the height of respective vertically-extending alignment guides 150. As noted above, the first die contacts 110a, first die block contacts 112a, and first die block contacts 112b (first alignment contacts 112b) may be formed as copper posts or pillars. In some examples, one or more additional plating processes may be performed to further extend the height of respective vertically-extending alignment guides 150, e.g., wherein lateral conductors 140, first die contacts 110a, first die block contacts 112a and 112b may be covered by photoresist or otherwise protected from such additional plating process(es).

In other examples, vertically-extending alignment guides 150 may be formed separately from the formation of the conductive layer 220 discussed above with respect to FIG. 5 and the plating process(es) discussed above with respect to FIG. 6. For example, vertically-extending alignment guides 150 may be formed from a polymer or other material after forming the first die contacts 110a and first die block contacts 112a and 112b.

In the manner described above (e.g., with reference to FIGS. 5 and 6), first die contacts 110a and first die block contacts 112a and 112b may be formed concurrently.

As shown in FIG. 7, respective second dies 116 are positioned, aligned, and mounted to respective first die blocks 102 including respective first dies 108, to form a panel-level structure 225. For example, a respective second die 116 may be picked up and positioned over (e.g., held above or physically placed on) a respective first die block 102, e.g., using a pick-and-place machine (PPM), with the respective second die 116 arranged in a face-to-face orientation relative to the respective first die 108 in the respective first die block 102. The second die 116, arranged in the face-to-face orientation relative to the first die 108, may be spatially aligned (translationally and/or rotationally aligned in the x-y plane) relative to the first die block 102, and thus spatially aligned relative to the first die 108, using the PPM. In some examples, the vertically-extending alignment guides 150 may physically constrain the translational and/or rotational positioning of the second die 116 to guide or facilitate the spatial alignment of the second die 116 relative to the first die block 102.

In some examples, the PPM may set the second die 116 on the first die block 102 and then align the second die 116 relative to the first die block 102, e.g., by displacing and/or rotating the second die 116. In other examples, the PPM may align the second die 116 relative to the first die block 102 (e.g., by displacing and/or rotating the second die 116) while holding the second die 116 lifted above (i.e., spaced apart from) the first die block 102, and then after the alignment, lower the second die 116 down onto the first die block 102.

In some examples, the first die block contacts 112b (i.e., first alignment contacts 112b) and second die outer contacts 122b (i.e., second alignment contacts 122b) may be used to facilitate the alignment of the second die 116 on the first die block 102. For example, as shown in the illustrated example, respective first die block contacts 112b (i.e., first alignment contacts 112b) may (a) be located radially outward from respective first die block contacts 112a (with respect to a centroid of the first die block 102 in the x-y plane), and/or (b) be located near an outer perimeter of the first die block 102, (c) be spaced relatively far apart from each other, and/or (d) have a larger diameter (lateral width) than respective first die block contacts 112a; and similarly, the second die contacts 122b (i.e., second alignment contacts 122b) may (a) be located radially outward from respective second die contacts 122a (with respect to a centroid of the second die 116 in the x-y plane), and/or (b) be located near an outer perimeter of the second die 116, (c) be spaced relatively far apart from each other, and/or (d) have a larger diameter (lateral width) than respective second die contacts 112a.

In some examples, the second die 116 may be aligned relative to the first die block 102 by aligning respective second alignment contacts 122b with respective first alignment contacts 112b, wherein the relatively larger diameter of the second die contacts 122b and first die block contacts 112b (e.g., as compared with respective second die contacts 122a and first die block contacts 112a) may facilitate such alignment As discussed below, in some examples in which respective second alignment contacts 122b are not fully aligned with respective first alignment contacts 112b after alignment by the PPM, a solder reflow process may inherently bring respective second alignment contacts 122b further into alignment with respective first alignment contacts 112b, i.e., to reduce a misalignment between the second alignment contacts 122b and first alignment contacts 112b. Facilitated by the radially outward and/or relatively spaced-apart locations of the first alignment contacts 112b and second alignment contacts 122b (discussed above), when the second alignment contacts 122b are brought into alignment with the first alignment contacts 112b (e.g., by the PPM and/or by the solder reflow process), respective second die contacts 122a may also be inherently brought into alignment (or further into alignment) with respective first die block contacts 112a.

With the second die 116 spatially aligned relative to the first die block 102, respective contacts provided on the second die 116 (e.g., second die inner contacts 120, second die outer contacts 122a, and second die outer contacts 122b) are aligned with respective contacts provided on the first die block 102 (e.g., first die contacts 110, first die block contacts 112a, and first die block contacts 112b). For example, with the second die 116 spatially aligned relative to the first die block 102, second die inner contacts 120 are aligned with respective first die contacts 110, respective second die outer contacts 122a are aligned with respective first die block contacts 112a, and respective second die outer contacts 122b (i.e., second alignment contacts 122b) are aligned with respective first die block contacts 112b (i.e., first alignment contacts 112b).

After positioning and aligning the second die 116 on the first die block 102 as discussed above, the second die 116 may be bonded to the first die block 102. For example, the bonding process may include (a) bonding respective second die inner contacts 120 to respective first die contacts 110 to define respective inner electrical connections 130 between the second die 116 and first die 108, (b) bonding respective second die outer contacts 122a to respective first die block contacts 112a to define respective outer electrical connections 134 outside the lateral footprint FP₁₀₈ of the first die 108, and (c) bonding respective second die outer contacts 122b (i.e., second alignment contacts 122b) to respective first die block contacts 112b (i.e., first alignment contacts 112b) to define respective alignment connections 142.

The various contacts discussed above may be bonded by any suitable bonding process and/or using any suitable bonding material. For example, various contacts discussed above may be solder bonded (e.g., using a flux), bonded by thermocompression bonding, or bonded using an adhesive, without limitation. In some examples, the process may include (a) applying a solder flux to the respective contacts provided on one or both of the first die block 108 and the second die 116 (e.g., at any time prior to mounting the second die 116 on the first die block 108), (b) positioning and aligning the second die 116 relative to the first die block 102 (e.g., as discussed above), (c) performing a mass reflow process across the panel-level substrate 200 to form respective solder bonds 230, and (d) applying and curing a liquid underfill (e.g., a low viscosity epoxy/polymer) that flows into voids located between the second die 116 and first die block 102 by capillary action, e.g., to seal the resulting structure. In other examples, the process may include (a) applying a combination flux/underfill material to one or both of the first die block 108 and the second die 116 (e.g., at any time prior to mounting the second die 116 on the first die block 108), (b) positioning and aligning the second die 116 relative to the first die block 102 (e.g., as discussed above), and (c) performing a mass reflow process across the panel-level substrate 200 to form respective solder bonds 230. In some examples, the solder reflow performed in the example processes discussed above may inherently bring respective second alignment contacts 122b further into alignment with respective first alignment contacts 112b (i.e., to reduce a misalignment between the second alignment contacts 122b and first alignment contacts 112b), which may inherently also bring respective second die contacts 122a further into alignment with respective first die block contacts 112a.

After bonding the respective second dies 116 to respective first die blocks 102 as discussed above, the panel-level structure 225 may be cut (e.g., saw cut or laser cut) along respective cut lines 240 to define an array of singulated example multi-die IC devices 100. FIG. 8 shows one singulated multi-die IC device 100, e.g., corresponding with the example multi-die IC device 100 shown in FIG. 1.

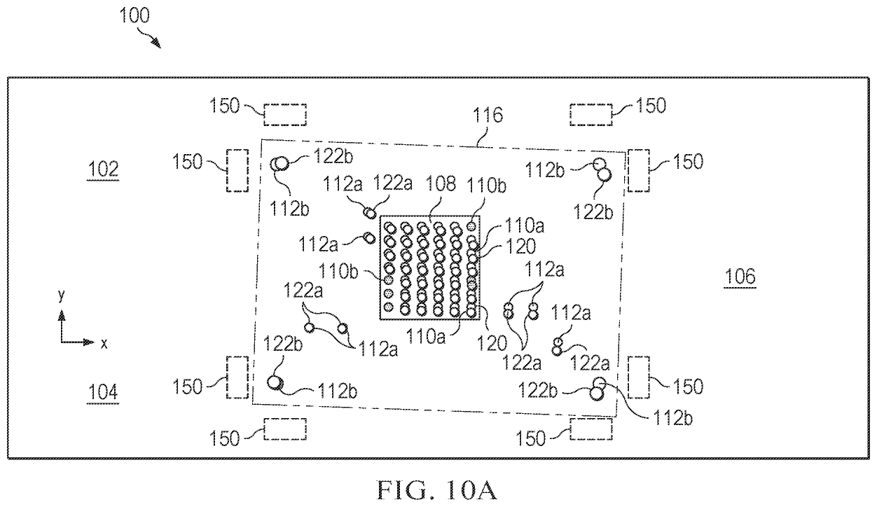

FIGS. 9A-9C illustrate three example IC packages including the multi-die IC device 100 discussed above.

FIG. 9A is a side cross-sectional view of an example flat no-leads IC package 900a including the example multi-die IC device 100 mounted to a leadframe 904. In some examples, the IC package 900a may be a quad flat no-leads (QFN) package wherein the leadframe 904 comprises a QFN leadframe. The multi-die IC device 100 may be mounted to the leadframe 904 using solder balls 906 at or near a lateral periphery of the first die block 102, e.g., to thereby define electrical connections between (a) respective leadframe leads 910 and a respective element of the first die 108 and/or the second die 116 (e.g., respective first die contacts 110a, first die contacts 110b, second die contacts 122a, or second die contacts 122b) via respective lateral conductors 140. The multi-die IC device 100 may be encapsulated by a mold compound or other encapsulant 914. In other examples, a thick solder paste, e.g., a tin/silver/copper (SnAgCu) paste, may be applied on the leadframe leads 910 and bonded to the multi-die IC device 100 by a reflow assembly process.

FIG. 9B is a side cross-sectional view of an example flat no-leads IC package 900b including a modified version of the example multi-die IC device 100 encapsulated by a mold compound or other encapsulant 914, wherein respective leads 920 extending from, or otherwise connected to, respective lateral conductors 140 may be formed integral with the first die block 102. In some examples, the IC package 900b may be a QFN package wherein the respective leads 920 define a QFN leadframe pattern.

FIG. 9C is a side cross-sectional view of an example IC package 900c including the example multi-die IC device 100 encapsulated by a mold compound or other encapsulant 914 and including peripheral bond pads 930 wire bonded to an electronic device 932, e.g., a quad flat pack (QFP), ball grid array (BGA), or other electronic device. Respective peripheral bond pads 930 may comprise, or may be coupled to, respective lateral conductors 140. In some examples, peripheral bond pads 930 may comprise gold, aluminum, or silver.

FIGS. 10A and 10B illustrate an example positioning and alignment of the second die 116 relative to the first die block 102. FIGS. 10A and 10B are representative top views showing selected elements of the example multi-die IC device 100. As shown in FIG. 10A, the second die 116 may be positioned over first die block 102, e.g., by a PPM as discussed above. The position of the second die 116 may be constrained by respective alignment guides 150, e.g., to facilitate an initial alignment of the second die 116 relative to the first die block 102. As shown in FIG. 10A, the second die 116 may be partially misaligned relative to the first die block 102, in at least one translational and/or rotational direction. In the illustrated example the second die 116 is misaligned rotationally about the z-axis relative to the first die block 102, and also misaligned translationally in the y-direction relative to the first die block 102. Due to the misalignment of the second die 116 relative to the first die block 102, respective smaller-diameter contacts of the second die 116 (e.g., second die inner contacts 120 and second die outer contacts 122a) may be substantially or fully misaligned (substantially or fully non-overlapping) relative to respective smaller-diameter contacts of the first die block 102 (e.g., first die contacts 110a and first die block contacts 112a), whereas respective larger-diameter second alignment contacts 122b may be less misaligned relative to the respective first alignment contacts 112b, resulting from the relatively larger diameter of the first and second alignment contacts 112b, 122b.

As discussed above, the second die 116 may be aligned relative to the first die block 102 by aligning (e.g., improving the alignment of) the second alignment contacts 122b relative to the respective first alignment contacts 112b. As shown in FIG. 10B, such alignment may involve rotating the second die 116 about the z-axis (as indicated by R_{z}) and translating the second die 116 in the y-direction (as indicated by T_{y}). Aligning the second alignment contacts 122b relative to the respective first alignment contacts 112b (to thereby improved the alignment of the second die 116 relative to the first die block 102) may be performed in one or more manners. For example, a PPM holding the second die 116 may rotate and/or translate the second die 116 relative to the first die block 102 to bring the second alignment contacts 122b into better alignment with the first alignment contacts 112b. In addition, or alternatively, a solder process (e.g., using a solder flux applied between respective second alignment contacts 122b and respective first alignment contacts 112b) may inherently generate attraction forces that bring respective second alignment contacts 122b into better alignment with respective first alignment contacts 112b. As shown in FIG. 10B, when second alignment contacts 122b become aligned with first alignment contacts 112b, the other contacts of the second die 116 (e.g., second die inner contacts 120 and second die outer contacts 122a) inherently become better aligned with respective contacts of the first die block 102 (e.g., first die contacts 110a and first die block contacts 112a).

FIGS. 11A and 11B illustrate another example multi-die IC device 1100. FIG. 11A shows a top view of device 1100 indicated at line 11A-11A shown in FIG. 11B, and FIG. 11B shows a cross-sectional side view of device 1100 indicated at line 11B-11B shown in FIG. 11A.

As shown in FIGS. 11A-11B, device 1100 includes a first die block 1102 and a second die 1116 mounted to the first die block 1102. The first die block 1102 includes a first die block substrate 1104 comprising a mold compound 1106, a first die 1108 at least partially embedded in the first die block substrate 1104, a plurality of first die contacts 1110a and 1110b, and a plurality of first alignment contacts 1112. The mold compound 106 may comprise an epoxy mold compound (EMC) or other suitable dielectric compound.

In some examples, the first die 1108 comprises a digital die, and the second die 1116 comprises an analog die. For example, device 1100 may comprise a heterogenous microcontroller, wherein the first die 1108 includes digital component(s) and the second die 1116 includes analog component(s) of the heterogenous microcontroller.

The second die 1116 may be mounted to the first die block 1102 in a face-to-face orientation, i.e., wherein the second die 1116 and first die 1108 are arranged in a face-to-face orientation. Unlike the example device 100 discussed above (in which the second die 116 has a larger lateral footprint than the first die 108), the second die 1116 has a lateral footprint FP₁₁₁₆ having the same or similar area as a lateral footprint FP₁₁₀₈ of the first die 1108. For example, in some examples an area of the second die lateral footprint FP₁₁₁₆ differ from an area of the first die lateral footprint FP₁₁₀₈ by less than 25%.

As a result, unlike the example device 100 discussed above, conductive contacts between the first die 1108 and second die 1116 may be contained within the first die lateral footprint FP₁₁₀₈.

The second die 1116 includes (a) a plurality of second die contacts 1120a bonded to respective first die contacts 1110a to define a plurality of electrical connections 1130 between the second die 1116 and first die 1108, (b) one or more second die contacts 1120b connected directly to respective lateral conductors 1140 (discussed below), and (c) a plurality of second alignment contacts 1122 bonded to respective alignment contacts 1112 to define a plurality of alignment connections 1142 between the second die 1116 and first die 1108. Respective alignment connections 1142 may or may not also define respective electrical connections 1130 between the second die 1116 and first die 1108 (similar to respective alignment connection 142, which may or may not also define respective electrical connections 130 between the second die 116 and first die 108 of the example device 100 discussed above).

Respective ones of the first die contacts 1110a, 1110b, first alignment contacts 1112, second die contacts 1120a, 1120b, and second alignment contacts 1122 may comprise any suitable type or types of conductive contacts, including for example (a) conductive pillars (e.g., copper pillars suitable for copper pillar bumping), (b) contact pads, e.g., solder wettable pads or solder plated pads (e.g., SnAgCu plated pads), or other type(s) of conduct contact structures. Conductive pillars may extend (in the z-direction) from an outer surface of the respective first die 1108 or second die 1116. Contact pads may be flush with, or may extend (in the z-direction) from, an outer surface of the respective first die 1108 or second die 1116 in the z-direction.

Respective second die contacts 1120a may be bonded to respective first die contacts 1110a (to form respective electrical connections 1130), and respective second alignment contacts 1122 may be bonded to respective alignment contacts 1112 (to define respective alignment connections 142) using any suitable bonding process and/or materials. For example, respective contacts may be bonded together by soldering, by thermocompression bonding, or using an adhesive. FIG. 11B shows example solder bonds 1160 between respective conductive elements of the example device 1100. In some examples, second die contacts (e.g., contacts 1120a and/or 1122) may be bonded to respective first die contacts (e.g., contacts 1110a and/or 1112) using a solder reflow process, which may improve an alignment (translational and/or rotational alignment) of the second die 1116 relative to the first die 1108, e.g., as discussed above with respect to the example device 100.

The first die block 1102 may include laterally extending conductors 1140 (also referred to as lateral conductors, for convenience) extending laterally (e.g., in the x-direction and/or y-direction shown in FIGS. 11A-11B) on a top surface of the first die block substrate 1104 and/or embedded within the first die block substrate 1104. Respective lateral conductors 1140 may extend laterally into and within a region vertically between the first die 1108 and second die 1116 (i.e., within the first die lateral footprint FP₁₁₀₈ and the second die lateral footprint FP₁₁₁₆) to electrically connect to respective first die contacts 1110b, respective second die contacts 1120b, respective electrical connections 1130, and/or respective alignment connections 1142, for example to allow electrical connection between the first die 1108 and/or the second die 1116 and external electronics (i.e., external to device 1100). Lateral conductors 1140 may comprise conductive traces, wires, metal lines, or other conductive elements. The example shown in FIGS. 11A-11B includes lateral conductors 1140 (e.g., copper traces or wires) formed on a top side of the first die block 1104.

Some lateral conductors 1140 may define or may be coupled to a respective external contact 144 (e.g., a lead or bond pad) located outside the first die lateral footprint FP₁₁₀₈ and second die lateral footprint FP₁₁₁₆, for bonding or otherwise connecting the device to one or more external electronics, e.g., by solder ball and/or wire bond connections. In some examples, the device 1100 comprises a quad flat no-leads (QFN) package, or a component of a QFN package, wherein lateral conductors 1144 define solder lands or pads.

The first die block 1102 may optionally include vertically-extending alignment guides 1150 projecting upwardly from the first die block substrate 1104. Vertically-extending alignment guides 1150 may be similar to vertically-extending alignment guides 150 of the example device 100 discussed above.

Although example embodiments have been described above, other variations and embodiments may be made from this disclosure without departing from the spirit and scope of these embodiments.

1. A method, comprising:
forming an integrated circuit (IC) device, wherein forming the IC device includes:
forming a first die block including:
a first die block substrate comprising a mold compound;
a first die at least partially embedded in the first die block substrate;
a plurality of first die contacts located in a lateral footprint of the first die; and
a plurality of first die block contacts located laterally outside the lateral footprint of the first die;
arranging a second die in a face-to-face orientation relative to the first die, wherein a lateral footprint of the second die is larger than a lateral footprint of the first die, and wherein the second die includes (a) a plurality of second die inner contacts and (b) a plurality of second die outer contacts;
spatially aligning the second die relative to the first die block; and
performing a bonding process to bond the second die to the first die block, wherein the bonding process includes (a) bonding respective second die inner contacts to respective first die contacts to define a plurality of inner electrical connections between the second die and the first die and (b) bonding respective second die outer contacts to respective first die block contacts to define a plurality of outer electrical connections outside the lateral footprint of the first die.

2. The method of claim 1, wherein the first die block includes a laterally extending conductor formed over the first die block substrate, the laterally extending conductor connected to a respective one of the plurality of first die block contacts and extending laterally outside the lateral footprint of the second die;
wherein the laterally extending conductor comprises a bond pad for bonding the IC device to another IC device.

3. The method of claim 2, wherein the respective first die block contact is bonded to a respective one the second die outer contacts to define an electrical connection between the laterally extending conductor and the second die.

4. The method of claim 1, wherein the first die block includes a plurality of laterally extending conductors, wherein respective laterally extending conductors define electrical connections between the first die and respective ones of the plurality of first die block contacts located laterally outside the lateral footprint of the first die.

5. The method of claim 1, wherein:
the plurality of first die contacts comprise a first plurality of pillars extending upwardly from a first side of the first die; and
the plurality of first die block contacts comprise a second plurality of pillars extending upwardly from the first die block substrate.

6. The method of claim 1, wherein after spatially aligning the second die relative to the first die block, the plurality of first die contacts and the plurality of first die block contacts are located in the lateral footprint of the second die.

7. The method of claim 1, wherein:
one or more first die block contacts of the plurality of first die block contacts define one or more first alignment contacts;
one or more second die outer contacts of the plurality of second die outer contacts define one or more second alignment contacts; and
spatially aligning the second die relative to the first die block comprises aligning the one or more second alignment contacts with the one or more first alignment contacts; and
the method comprises bonding respective second alignment contacts to respective first alignment contacts.

8. The method of claim 7, wherein a respective diameter of a respective first alignment contact of the one or more first alignment contacts is larger than a respective diameter of a respective first die contact of the plurality of first die contacts.

9. The method of claim 7, wherein a respective diameter of a respective second alignment contact of the one or more second alignment contacts is larger than a respective diameter of a respective second die outer contact of the plurality of second die outer contacts.

10. The method of claim 1, wherein the first die comprises a digital die, and the second die comprises an analog die.

11. The method of claim 1, comprising providing a flux between the first die and the second die prior to performing the bonding process, and wherein the bonding process comprises a mass reflow process.

12. The method of claim 1, comprising forming the plurality of first die contacts and the plurality of first die block contacts concurrently.

13. The method of claim 1, wherein:
forming the first die block includes forming at least one vertically-extending alignment guide; and
spatially aligning the second die relative to the first die block comprises using the at least one vertically-extending alignment guide to physically constrain a spatial alignment of the second die relative to the first die block.

14. The method of claim 1, comprising:
forming a panel-level structure, including:
arranging a plurality of first dies, including the first die, on a panel-level carrier; and
overmolding the plurality of first dies to form a panel-level substrate with the plurality of first dies embedded in the panel-level substrate;
wherein a respective portion of the panel-level substrate defines the first die block substrate, and wherein the first die block includes the first die block substrate having the first die embedded therein; and
after aligning and bonding the second die to the first die block, performing a singulation process to singulate the first die block having the first die embedded therein and the second die mounted thereto.

15. The method of claim 1, comprising mounting the IC device in a quad flat no-leads (QFN) package.

16. An integrated circuit (IC) device, comprising:
a first die block including:
a first die block substrate comprising a mold compound;
a first die at least partially embedded in the first die block substrate;
a plurality of first die contacts located in a lateral footprint of the first die; and
a plurality of first die block contacts located laterally outside the lateral footprint of the first die;
a second die mounted to the first die in a face-to-face orientation;
wherein a lateral footprint of the second die is larger than a lateral footprint of the first die; and
wherein the second die includes:
a plurality of second die inner contacts bonded to respective ones of the plurality of first die contacts to define a plurality of inner electrical connections between the second die and the first die; and
a plurality of second die outer contacts bonded to respective ones of the plurality of first die block contacts to define plurality of outer electrical connections outside the lateral footprint of the first die.

17. The IC device of claim 16, comprising a laterally extending conductor formed over the first die block substrate, wherein the laterally extending conductor is electrically connected to the second die through a respective one of the plurality of first die block contacts and a respective one of the plurality of second die outer contacts.

18. The IC device of claim 16, wherein the first die comprises a digital die, and the second die comprises an analog die.

19. An integrated circuit (IC) device, comprising:
a first die block including:
a first die block substrate comprising a mold compound;
a first die at least partially embedded in the first die block substrate, the first die having a first die lateral footprint;
a plurality of first die contacts located within the first die lateral footprint; and
a second die mounted to the first die in a face-to-face orientation, the second die having a second die lateral footprint;
wherein the second die includes a plurality of second die contacts located within the second die lateral footprint, wherein respective second die contacts are bonded to respective first die contacts to define a plurality of electrical connections between the second die and the first die; and
a laterally extending conductor formed on or in the first die block, wherein the laterally extending conductor (a) is connected to at least one of a respective first die contact or a respective second die contact at a respective location within the first die lateral footprint and the second die lateral footprint, (b) extends laterally outside the first die lateral footprint and the second die lateral footprint, and (c) is connected to or defines an external contact.

20. The IC device of claim 19, wherein an area of the second die lateral footprint differs from an area of the first die lateral footprint by less than 25%.
